(19) United States
(12) Patent Application Publication
(10) Pub. No.: US 2018/0293971 A1
(43) Pub. Date: Oct. 11, 2018

(54) APPARATUS FOR PLAYING SOUND INDOORS USING SOUND TRANSMISSION PIPES AND METHOD FOR THE SAME

(71) Applicant: Sonictier, Inc., Paju-si (KR)

(72) Inventors: Seung-Min Park, Seoul (KR); Jun-Seo Park, Seoul (KR); Nam-Hoon Kwak, Seoul (KR)

(73) Assignee: Sonictier, Inc., Paju-si (KR)

(21) Appl. No.: 15/940,798

(22) Filed: Mar. 29, 2018

(30) Foreign Application Priority Data
Apr. 10, 2017 (KR) 10-2017-0046113

(51) Int. Cl. G10K 11/22; A63J 25/00; H03F 1/32; G10K 11/02; H04R 1/02

(52) U.S. Cl. CPC G10K 11/22; A63J 25/00; H03F 1/3241; G01N 2291/023; H04R 1/02; G01N 2291/02854; G10K 11/02

(57) ABSTRACT

Disclosed herein is an apparatus for playing sounds indoors using sound transmission pipes, which includes a processor for extracting audio signals of one or more channels from source data and creating audio signals to be output, speakers for outputting the audio signals, and sound transmission pipes, connected with remote speakers that are parts of the speakers, for transmitting output sounds corresponding to the remote speakers.

### CROSS REFERENCE TO RELATED APPLICATION

This application claims the benefit of Korean Patent Application No. 10-2017-0046113, filed Apr. 10, 2017, which is hereby incorporated by reference in its entirety into this application.

### BACKGROUND OF THE INVENTION

### 1. Technical Field

The present invention relates generally to an apparatus and method for playing sounds indoors, and more particularly to an apparatus and method for playing sounds indoors using sound transmission pipes.

### 2. Description of the Related Art

These days, when a movie is screened in a theater, the movie can be extended onto side screens in order to make the movie more immersive. That is, the scenes of a movie are extended onto the side walls of a theater, whereby a 3D effect and a sense of space are improved from the aspect of visual effects. Also, in order to improve a 3D effect from the aspect of sound, stereophonic and 3D sound techniques have been developed.

FIG. 1 is a view that shows an example of a multi-channel sound system according to the conventional art.

Referring to FIG. 1, the multi-channel sound system is configured with a total of 30.2 channels, including 15 front channels, 6 side surround channels, 3 rear surround channels, 6 top channels, and 0.2 front and rear woofer channels. Particularly, because sounds associated with objects currently being displayed on the screen are output using front speakers arranged in the form of a 5×3 array, movie audiences may enjoy realistic sounds associated with the objects.

FIG. 2 is a view that shows an example of an indoor multi-channel sound system according to the conventional art.

Referring to FIG. 2, the indoor multi-channel sound system according to the conventional art includes a front channel and side surround channels in the state in which a screen 210 is installed in front. Here, speakers 221, 222, 223, 231, 232 and 233 that form the side surround channels protrude from side walls due to their volumes.

Additionally, in order to improve the realism of sounds, speakers may be arranged behind a screen such that it seems as if sounds are output directly from objects being displayed on the screen. However, when side screens are installed in an existing theater in order to extend a movie onto the side screens, it is problematic in that more space is required due to the fact that the speakers protrude from the side walls of the theater. Also, when a screen is installed in a small space, it is difficult to allocate space for speakers because there is not enough space behind the screen.

Accordingly, in order to provide highly immersive sound with the development of technology for displaying images on extended screens, there is required a method for outputting sounds from the backside of a screen in spite of the small space behind the screen.

### DOCUMENTS OF RELATED ART

(Patent Document 1) Korean Patent No. 10-1115687.

### SUMMARY OF THE INVENTION

An object of the present invention is to output sounds indoors using sound transmission pipes.

Another object of the present invention is to compensate for distortion by performing predistortion on audio signals to be output in consideration of the fact that output sounds are distorted while being transmitted through sound transmission pipes.

A further object of the present invention is to complement predistortion using output sounds that are transmitted through sound transmission pipes.

An embodiment of the present invention provides an apparatus for playing sounds indoors using sound transmission pipes, which includes a processor for extracting audio signals of one or more channels from source data and creating audio signals to be output; speakers for outputting the audio signals; and sound transmission pipes, connected with remote speakers that are parts of the speakers, for transmitting output sounds corresponding to the remote speakers.

Here, the processor may create predistortion parameters using sound transmission pipe parameters and thereby perform predistortion for the audio signals to be output, and the sound transmission pipe parameters may include information about at least one of a material, a length, a size, and a shape of each of the sound transmission pipes.

Here, the audio signals may include side audio signals, among multi-channel audio signals, and the sound transmission pipes may be symmetrically installed on left and right sides of an indoor space.

Here, the apparatus may further include feedback microphones for creating feedback audio signals by receiving sounds transmitted through the sound transmission pipes, and the processor may perform supplementary distortion for the audio signals to be output, on which predistortion has been performed, using the feedback audio signals.

Here, the predistortion may include distortion for a video signal to be output, and the predistortion parameters may include delay adjustment information for at least one of the video signal to be output and the audio signals to be output.

Here, the delay adjustment information may be created based on a delay of the output sound corresponding to a longest sound transmission pipe of the sound transmission pipes.

Here, the predistortion parameters may include equalization adjustment information for at least one of the audio signals to be output.

Here, the predistortion parameters may include level adjustment information for at least one of the audio signals to be output.

Another embodiment of the present invention provides a method for playing sounds indoors using sound transmission pipes, which includes extracting audio signals of one or more channels from source data and creating audio signals to be output; outputting the audio signals using speakers; and transmitting output sounds corresponding to remote speakers, which are parts of the speakers, through sound transmission pipes connected with the remote speakers.

Here, creating the audio signals may include creating predistortion parameters using sound transmission pipe parameters; and performing predistortion for the audio signals to be output using the predistortion parameters, and the sound transmission pipe parameters may include information about at least one of a material, a length, a size, and a shape of each of the sound transmission pipes.

Here, the audio signals may include side audio signals, among multi-channel audio signals, and the sound transmission pipes may be symmetrically installed on left and right sides of an indoor space.

Here, the method may further include creating feedback audio signals by receiving sounds transmitted through the sound transmission pipes, and creating the audio signals may further include performing supplementary distortion for the audio signals to be output, on which predistortion has been performed, using the feedback audio signals.

Here, the predistortion may include distortion for a video signal to be output, and the predistortion parameters may include delay adjustment information for at least one of the video signal to be output and the audio signals to be output.

Here, the delay adjustment information may be created based on a delay of the output sound corresponding to a longest sound transmission pipe of the sound transmission pipes.

Here, the predistortion parameters may include equalization adjustment information for at least one of the audio signals to be output.

Here, the predistortion parameters may include level adjustment information for at least one of the audio signals to be output.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view that shows an example of a multi-channel sound system according to the conventional art;

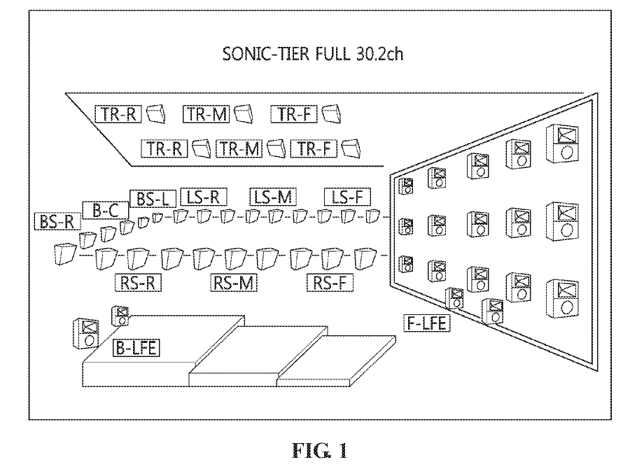

FIG. 2 is a view that shows an Example of an indoor multi-channel sound system according to the conventional art;

FIG. 3 is a block diagram that shows an apparatus for playing sounds indoors using sound transmission pipes according to an embodiment of the present invention;

FIG. 4 is a flowchart that shows a method for playing sounds indoors using sound transmission pipes according to an embodiment of the present invention;

FIG. 5 is a flowchart that shows an example of the step of performing predistortion, illustrated in FIG. 4;

FIG. 6 is a view that shows an example of a speaker and a sound transmission pipe according to the present invention;

FIG. 7 is a view that shows an example of an indoor multi-channel sound system according to an embodiment of the present invention;

FIG. 8 is a view that shows an example of a video signal and audio signals to be output, on which predistortion is not yet performed, according to the present invention;

FIG. 9 is a view that shows an example of the result of adjustment of delay in the example illustrated in FIG. 8 according to an embodiment of the present invention;

FIG. 10 is a view that shows an example of the result of adjustment of a level in the example illustrated in FIG. 9 according to an embodiment of the present invention; and

FIG. 11 is a view that shows an example of the result of performing adjustment in the example illustrated in FIG. 10 according to an embodiment of the present invention.

### DESCRIPTION OF THE PREFERRED EMBODIMENTS

The present invention may be variously changed, and may have various embodiments, and specific embodiments will be described in detail below with reference to the attached drawings. The effects and features of the present invention and methods of achieving them will be apparent from the following exemplary embodiments, which will be described in more detail with reference to the accompanying drawings. Repeated descriptions and descriptions of known functions and configurations which have been deemed to make the gist of the present invention unnecessarily obscure will be omitted below. The embodiments of the present invention are intended to fully describe the present invention to a person having ordinary knowledge in the art to which the present invention pertains. Accordingly, the shapes, sizes, etc. of components in the drawings may be exaggerated in order to make the description clearer.

However, the present invention is not limited to the embodiments to be described below, and all or some of the embodiments may be selectively combined and configured, so that the embodiments may be modified in various ways. It will be understood that, although the terms “first,” “second,” etc. may be used herein to describe various elements, these elements are not intended to be limited by these terms. These terms are only used to distinguish one element from another element. Also, a singular expression includes a plural expression unless a description to the contrary is specifically pointed out in context. Also, it should be understood that terms such as “include” or “have” are merely intended to indicate that features, components, parts, or combinations thereof are present, and are not intended to exclude the possibility that one or more other features, components, parts, or combinations thereof will be present or added.

Hereinafter, embodiments of the present invention will be described in detail with reference to the accompanying drawings. In the following description of the present invention, the same reference numerals are used to designate the same or similar elements throughout the drawings, and repeated descriptions of the same components will be omitted.

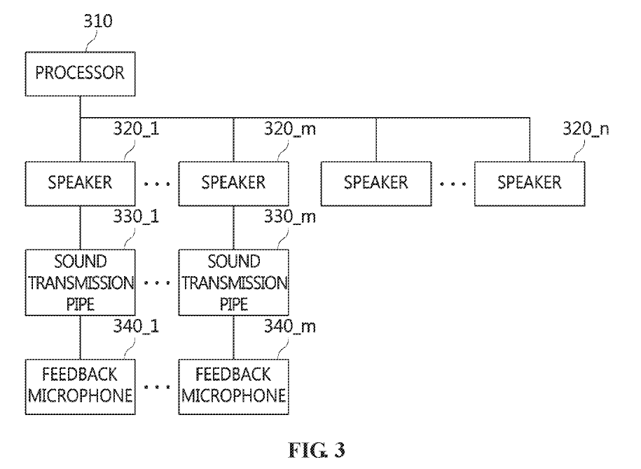

FIG. 3 is a block diagram that shows an apparatus for playing sounds indoors using sound transmission pipes according to an embodiment of the present invention.

Referring to FIG. 3, the apparatus for playing sounds indoors using sound transmission pipes according to an embodiment of the present invention includes a processor 310, speakers 320_1 to 320_n, and sound transmission pipes 330_1 to 330_m.

Also, the apparatus for playing sounds indoors using sound transmission pipes according to an embodiment of the present invention may further include feedback microphones 340_1 to 340_m.

Specifically, the processor 310 extracts audio signals of one or more channels from source data and creates audio signals to be output.

Here, the source data are source data for a video or sound source that is intended to be output, and include audio data. Particularly, when the source data are source data for video, the source data may further include video data.

For example, the source data may be media in which both audio and video are included, such as a movie, a documentary, a drama, or the like.

Here, the processor 310 may create predistortion parameters using sound transmission pipe parameters. Also, using the predistortion parameters, the processor 310 may perform predistortion for each of the audio signals to be output.

Here, the sound transmission pipe parameters may include information about at least one of the material, the length, the size, and the shape of each of the sound transmission pipes 330_1 to 330_m.

Also, the predistortion parameters may include delay adjustment information, equalization adjustment information, level adjustment information, and the like for the audio signals to be output.

Accordingly, even though output sounds are transmitted through the sound transmission pipes 330_1 to 330_m, undistorted sounds may be listened to indoors.

Here, the audio signals may include side audio signals, among multi-channel audio signals.

Here, predistortion may include distortion of a video signal to be output, and the predistortion parameters may include information for adjusting the delay of the video signal to be output. Particularly, using the predistortion parameters, the processor 310 may adjust the delay of the video signal to be output.

Accordingly, the sounds to be listened to indoors may be output so as to be synchronized with the output video.

Here, the delay adjustment information may be created based on the delay that is caused when a sound passes through the longest sound transmission pipe of the sound transmission pipes 330_1 to 330_m.

Here, sounds, corresponding to the audio signals output from the speakers 320_1 to 320_n, do not directly reach the indoor space in which a listener is located, but some of the output sounds pass through the sound transmission pipes 330_1 to 330_m before reaching the indoor space. Therefore, it is necessary to adjust the delay. The speed at which a sound travels is about 340 m/s, and it takes certain time for a sound to pass through the sound transmission pipes 330_1 to 330_m. Because human ears are capable of discerning a minute difference of time, the delay of the audio signals to be output is adjusted using information about the lengths of the sound transmission pipes 330_1 to 330_m, whereby it is possible for the output sounds to simultaneously reach the indoor space even after passing through the sound transmission pipes 330_1 to 330_m

Particularly, because it takes the longest time for a sound to pass through the longest sound transmission pipe, among the sound transmission pipes 330_1 to 330_m, delay information may be created based on the delay that is caused when a sound passes through the longest sound transmission pipe.

For example, if the delay caused when a sound passes through the longest sound transmission pipe is t seconds, delay adjustment information may be created such that the delay of a video signal to be output and audio signals corresponding to sounds transmitted without passing through the sound transmission pipes 330_1 to 330_m is set to t seconds. Then, delay adjustment information in which the delay of the remaining audio signals is set to be equal to or less than t seconds may be created using information about the lengths of the respective sound transmission pipes 330_1 to 330_m.

Also, because the output sounds may be distorted while being transmitted through the sound transmission pipes 330_1 to 330_m, it is necessary to adjust equalization. The degree of distortion may vary in each frequency band depending on the material, the length, the size, and the shape of the sound transmission pipes. Accordingly, equalization of the audio signals to be output is adjusted using the sound transmission pipe parameters, whereby sounds matching the source data may be realized when the output sounds reach the indoor space after passing through the sound transmission pipes 330_1 to 330_m.

Furthermore, it is necessary to adjust a sound level because the level of the output sounds may decrease while the output sounds are being transmitted through the sound transmission pipes 330_1 to 330_m. Also, when a screen is arranged in front of the sound transmission pipes 330_1 to 330_m, the level of the output sounds passing through the sound transmission pipes 330_1 to 330_m may further decrease due to the screen. Accordingly, the level of the audio signals to be output is adjusted using the sound transmission pipe parameters, whereby the output sounds may reach a preset level when they arrive at the indoor space after passing through the sound transmission pipes 330_1 to 330_m.

For example, if the present invention is implemented in a theater, when a screen is located in front of speakers, the level of sounds for the speakers may be adjusted such that the level of the sounds that reach the indoor space becomes about 85 dB. When there is no screen in front of the speakers, the level of sounds for the speakers may be adjusted such that the level of the sounds that reach the indoor space becomes about 83 dB. Particularly, when a screen is located in front of the ends of the sound transmission pipes, the level of sounds may be adjusted such that the level of the sounds to be transmitted to the indoor space via the sound transmission pipes becomes about 85 dB.

Here, using feedback audio signals created by the feedback microphones 340_1 to 340_m, the processor 310 may perform supplementary distortion for the output audio signals on which predistortion is performed.

For example, differential audio signals may be created by comparing feedback audio signals corresponding to the respective output audio signals on which predistortion is performed, and information for additionally adjusting the delay, the equalization, and the level thereof may be created using the differential audio signals.

Accordingly, even when predistortion performed on the audio signals to be output is defective, because supplementary distortion is performed, the reliability and accuracy of predistortion may be improved.

The speakers 320_1 to 320_n create sounds by outputting audio signals created by the processor 310. Here, the respective audio signals are output via the speakers corresponding to the set channels.

Here, each of remote speakers 320_1 to 320_m, which are some of the speakers 320_1 to 320_n, is interconnected with a corresponding one of the sound transmission pipes 330_1 to 330_m.

Here, some of the speakers 320_1 to 320_n may be sequentially arranged.

Here, some of the speakers 320_1 to 320_n may be arranged in a radial form in which they are arranged in multiple columns.

The sound transmission pipes 330_1 to 330_m are connected with the remote speakers 320_1 to 320_m, thereby transmitting the sounds output from the remote speakers 320_1 to 320_m to the indoor space.

Here, the sound transmission pipes 330_1 to 330_m have no limitation as to the length, the size, the shape, and the material thereof. Also, the sound transmission pipes 330_1 to 330_m may have different lengths, sizes, shapes, and materials.

Here, the sound transmission pipes to 330_1 to 330_m may be symmetrically installed on the left and right sides of the indoor space.

Here, the sound transmission pipes 330_1 to 330_m are installed inside space such as a wall or a stanchion, whereby the remote speakers 320_1 to 320_m connected with the sound transmission pipes 330_1 to 330_m may be located so as to be spatially separate from the indoor space.

The feedback microphones 340_1 to 340_m create feedback audio signals by receiving output sounds transmitted through the sound transmission pipes 330_1 to 330_m. Using the feedback audio signals, the sound to be listened to in the indoor space may be checked. Here, the feedback audio signals may be used when the processor 310 performs supplementary distortion for the output audio signals.

Here, each of the feedback microphones 340_1 to 340_m may be located at the end of a corresponding one of the sound transmission pipes 330_1 to 330_m.

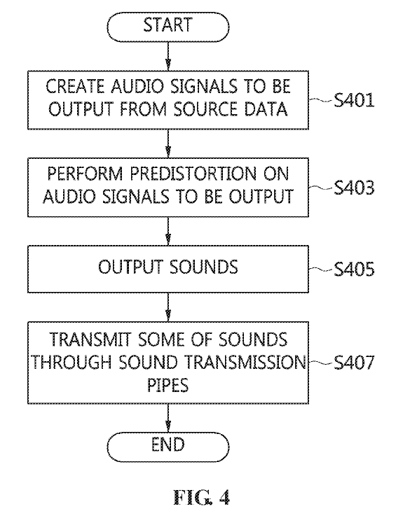

FIG. 4 is a flowchart that shows a method for playing sounds indoors using sound transmission pipes according to an embodiment of the present invention.

Referring to FIG. 4, in the method for playing sounds indoors using sound transmission pipes according to an embodiment of the present invention, audio signals of one or more channels are extracted from source data, and audio signals to be output are created at step S401.

Here, the source data are source data for a video or sound source that is intended to be output, and include audio data. Particularly, when the source data are source data for video, the source data may further include video data.

For example, the source data may be media in which both audio and video are included, such as a movie, a documentary, a drama, or the like.

Here, the audio signals may include side audio signals, among multi-channel audio signals.

Also, in the method for playing sounds indoors using sound transmission pipes according to an embodiment of the present invention, predistortion for each of the audio signals to be output is performed at step S403.

Here, predistortion parameters are created using sound transmission pipe parameters, and predistortion for each of the audio signals to be output may be performed using the predistortion parameters.

Here, the sound transmission pipe parameters may include information about at least one of the material, the length, the size, and the shape of sound transmission pipes (330_1 to 330_m in FIG. 3).

Also, the predistortion parameters may include delay adjustment information, equalization adjustment information, level adjustment information, and the like for the audio signals to be output.

Accordingly, even though the output sounds are transmitted through the sound transmission pipes (330_1 to 330_m in FIG. 3), undistorted sounds may be listened to indoors.

Here, predistortion may include distortion of a video signal to be output, and the predistortion parameters may include information for adjusting the delay of the video signal to be output. That is, the delay of the video signal to be output may be adjusted using the predistortion parameters.

Accordingly, the sounds to be listened to indoors may be output so as to be synchronized with the output video.

Here, using feedback audio signals created by feedback microphones (340_1 to 340_m in FIG. 3), supplementary distortion may be performed for the output audio signals on which predistortion is performed.

For example, differential audio signals may be created by comparing feedback audio signals corresponding to the respective output audio signals on which predistortion is performed, and information for additionally adjusting the delay, the equalization, and the level may be created using the differential audio signals.

Accordingly, even when predistortion performed on the audio signals to be output is defective, because supplementary distortion is performed, the reliability and accuracy of predistortion may be improved.

Also, in the method for playing sounds indoors using sound transmission pipes according to an embodiment of the present invention, the audio signals are output using speakers (320_1 to 320_n in FIG. 3) at step S405. Here the respective audio signals are output via speakers corresponding to the set channels.

Here, remote speakers (320_1 to 320_m in FIG. 3), which are some of the speakers (320_1 to 320_n in FIG. 3), are interconnected with the sound transmission pipes (330_1 to 330_m in FIG. 3).

Here, some of the speakers (320_1 to 320_n in FIG. 3) may be sequentially arranged.

Here, some of the speakers (320_1 to 320_n in FIG. 3) may be arranged in a radial form in which they are arranged in multiple columns.

Also, in the method for playing sounds indoors using sound transmission pipes according to an embodiment of the present invention, sounds output from the remote speakers (320_1 to 320_m in FIG. 3) are transmitted to the indoor space at step S407 via the sound transmission pipes (330_1 to 330_m in FIG. 3) connected with corresponding ones of the remote speakers (320_1 to 320_m in FIG. 3).

Here, the sound transmission pipes (330_1 to 330_m in FIG. 3) have no limitation as to the length, the size, the shape, and the material thereof. Also, the sound transmission pipes (330_1 to 330_m in FIG. 3) may have different lengths, sizes, shapes, and materials.

Here, the sound transmission pipes (330_1 to 330_m in FIG. 3) may be symmetrically installed on the left and right sides of the indoor space.

Here, the sound transmission pipes (330_1 to 330_m in FIG. 3) are installed inside space such as a wall or a stanchion, whereby the remote speakers (320_1 to 320_m in FIG. 3) corresponding to the sound transmission pipes (330_1 to 330_m in FIG. 3) may be located so as to be spatially separated from the indoor space.

Here, using the feedback microphones (340_1 to 340_m in FIG. 3), feedback audio signals may be created by receiving the output sounds transmitted through the sound transmission pipes (330_1 to 330_m in FIG. 3). Then, using the feedback audio signals, the sound to be listened to in the indoor space may be checked. Here, the feedback audio signals may be used to perform supplementary distortion for the output audio signals.

Here, each of the feedback microphones (340_1 to 340_m in FIG. 3) may be located at the end of a corresponding one of the sound transmission pipes (330_1 to 330_m in FIG. 3).

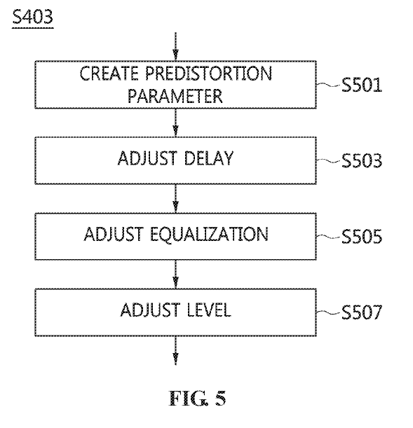

FIG. 5 is a flowchart that shows an example f the step (S403) of performing predistortion, illustrated in FIG. 4.

Referring to FIG. 5, in the step (S403) of performing predistortion, illustrated in FIG. 4, predistortion parameters are created at step S501 using sound transmission pipe parameters.

Here, the sound transmission pipe parameters may include information about at least one of the material, the length, the size, and the shape of sound transmission pipes (330_1 to 330_m in FIG. 3).

Also, in the step (S403) of performing predistortion, illustrated in FIG. 4, the delay of audio signals to be output may be adjusted at step S503 using the predistortion parameters.

Here, the predistortion parameters may include delay adjustment information for setting the delay of the video signal to be output. Accordingly, the delay of the video signal to be output may be adjusted using the predistortion parameters.

Here, the delay adjustment information may be created based on the delay that is caused when a sound passes through the longest sound transmission pipe of the sound transmission pipes (330_1 to 330_m in FIG. 3).

Here, sounds, corresponding to the audio signals output from the speakers (320_1 to 320_n in FIG. 3), do not directly reach the indoor space in which a listener is located, but some of the output sounds pass through the sound transmission pipes (330_1 to 330_m in FIG. 3) before reaching the indoor space. Therefore, it is necessary to adjust the delay. The speed at which a sound travels is about 340 m/s, and it takes certain time for a sound to pass through the sound transmission pipes (330_1 to 330_m in FIG. 3). Because human ears are capable of discerning a minute difference of time, the delay of audio signals to be output is adjusted using information about the lengths of the sound transmission pipes (330_1 to 330_m in FIG. 3), whereby it is possible for the output sounds to simultaneously reach the indoor space even after passing through the sound transmission pipes (330_1 to 330_m in FIG. 3).

Particularly, because it takes the longest time for a sound to pass through the longest sound transmission pipe, among the sound transmission pipes (330_1 to 330_m in FIG. 3), delay information may be created based on the delay caused when a sound passes through the longest sound transmission pipe.

For example, if the delay caused when a sound passes through the longest sound transmission pipe is t seconds, delay adjustment information may be created such that the delay of a video signal to be output and audio signals corresponding to sounds transmitted without passing through the sound transmission pipes (330_1 to 330_m in FIG. 3) is set to t seconds. Then, delay information in which the delay of the remaining audio signals is set to be equal to or less than t seconds may be created using information about the lengths of the respective sound transmission pipes (330_1 to 330_m in FIG. 3).

Also, in the step (S403) of performing predistortion, illustrated in FIG. 4, equalization of the audio signals to be output may be adjusted at step S505 using the predistortion parameters.

That is, because the output sounds may be distorted while being transmitted through the sound transmission pipes (330_1 to 330_m in FIG. 3), it is necessary to adjust equalization. The degree of distortion may vary in each frequency band depending on the material, the length, the size, and the shape of the sound transmission pipes. Accordingly, equalization of the audio signals to be output is adjusted using the sound transmission pipe parameters, whereby sounds matching the source data may be realized when the output sounds reach the indoor space after passing through the sound transmission pipes (330_1 to 330_m in FIG. 3).

Also, in the step (S403) of performing predistortion, illustrated in FIG. 4, the level of the audio signals to be output may be adjusted at step S507 using the predistortion parameters.

That is, it is necessary to adjust a sound level because the level of the output sounds may decrease while the output sounds are being transmitted through the sound transmission pipes (330_1 to 330_m in FIG. 3). Also, when a screen is arranged in front of the sound transmission pipes (330_1 to 330_m in FIG. 3), the level of the output sounds may further decrease due to the screen. Accordingly, the level of the audio signals to be output is adjusted using the sound transmission pipe parameters, whereby the output sounds may reach a preset level when they arrive at the indoor space after passing through the sound transmission pipes (330_1 to 330_m in FIG. 3).

For example, if the present invention is implemented in a theater, when a screen is located in front of speakers, the level of sounds for the speakers may be adjusted such that the level of the sounds that reach the indoor space becomes about 85 dB. When there is no screen in front of the speakers, the level of sounds for the speakers may be adjusted such that the level of the sounds that reach the indoor space becomes about 83 dB. Particularly, when a screen is located in front of the ends of the sound transmission pipes, the level of sounds may be adjusted such that the level of the sounds to be transmitted to the indoor space via the sound transmission pipes becomes about 85 dB.

In an alternative embodiment, among the above steps S501, S503, S505, and S507, adjusting a delay at step S503 and adjusting equalization at step S505 may be performed at the same time.

In an alternative embodiment, among the above steps S501, S503, S505, and S507, adjusting equalization at step S505 and adjusting a level at step S507 may be performed at the same time.

In an alternative embodiment, among the above steps S501, S503, S505, and S507, adjusting a delay at step S503, adjusting equalization at step S505, and adjusting a level at step S507 may be performed at the same time.

In an alternative embodiment, among the above steps S501, S503, S505, and S507, adjusting equalization at step S505 may be performed before adjusting a delay at step S503.

In an alternative embodiment, among the above steps S501, S503, S505, and S507, adjusting a level at step S507 may be performed before adjusting a delay at step S503.

In an alternative embodiment, among the above steps S501, S503, S505, and S507, adjusting a level at step S507 may be performed before adjusting equalization at step S505.

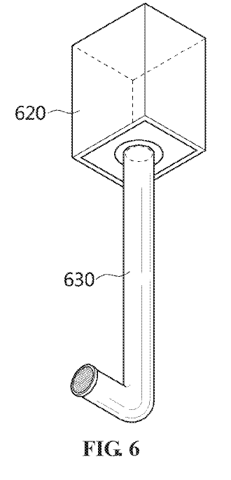

FIG. 6 is a view that shows an example of a speaker and a sound transmission pipe according to the present invention.

Referring to FIG. 6, the speaker 620 for outputting an audio signal is connected with the sound transmission pipe 630 for transmitting a sound output from the speaker 620.

Here, the speaker 620 and the sound transmission pipe 630 may correspond to each other in a one-to-one manner.

Here, the sound transmission pipe 630 may have the shape of an empty pipe, and has no limitation as to the material, the size, the shape, and the length thereof.

Also, the sound transmission pipe 630 and the speaker 620 may comprise multiple sound transmission pipes and multiple speakers, respectively.

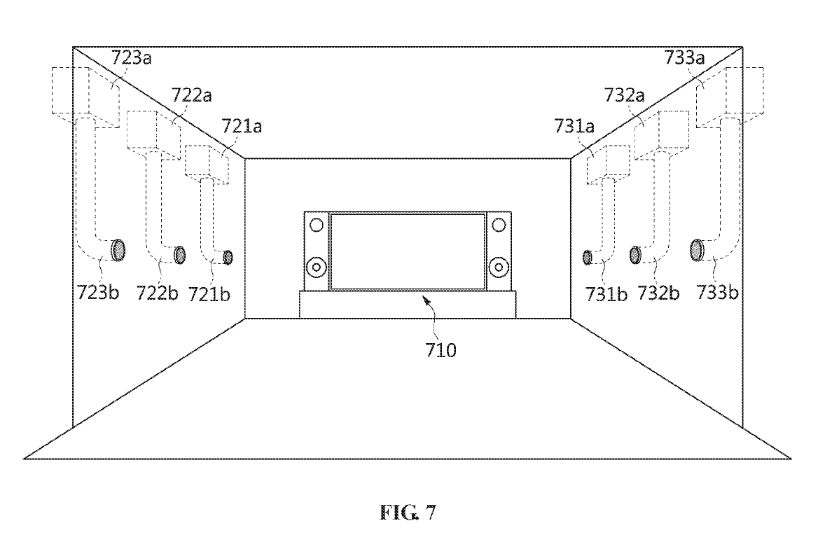

FIG. 7 is a view that shows an example of an indoor multi-channel sound system according to an embodiment of the present invention.

Referring to FIG. 7, the indoor multi-channel sound system according to an embodiment of the present invention includes a front channel and side surround channels in the state in which a screen 710 is installed in front.

However, the front screen 710 is not included in the apparatus for playing sounds indoors using sound transmission pipes according to an embodiment of the present invention.

Here, the speakers 721a, 722a, 723a, 731a, 732a and 733a for forming the side surround channels may be located inside walls or above the ceiling, rather than protruding from the side walls of the indoor space.

Particularly, the speakers 721a, 722a, 723a, 731a, 732a and 733a for forming the side surround channels have no limitation as to the locations thereof.

Also, the speakers 721a, 722a, 723a, 731a, 732a and 733a for forming the side surround channels are connected with the sound transmission pipes 721b, 722b, 723b, 731b, 732b and 733b, respectively, whereby output sounds are transmitted to the indoor space.

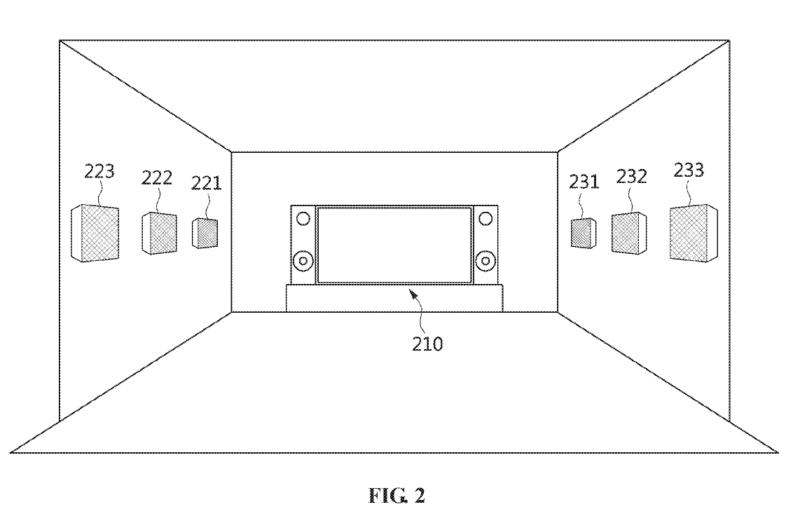

Because the output sounds are transmitted to the indoor space through the sound transmission pipes 721b, 722b, 723b, 731b, 732b and 733b, the speakers may occupy a small space without the need to protrude from the side walls of the indoor space, as opposed to the conventional speakers (221, 222, 223, 231, 232 and 233 in FIG. 2).

Accordingly, a sound system may be constructed using a smaller space than the space that has to date been required in order to install speakers.

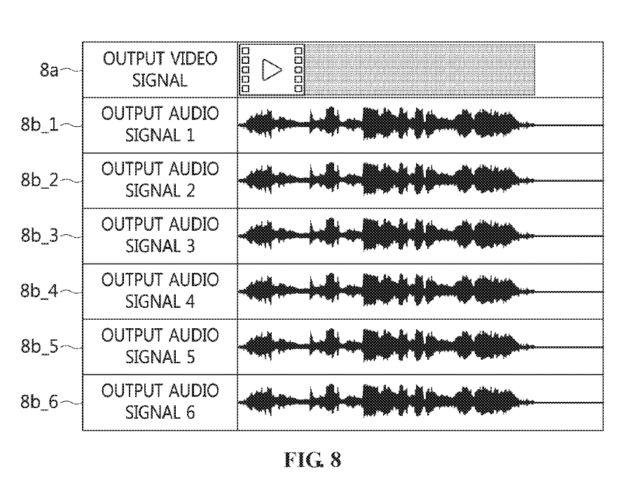

FIG. 8 is a view that shows an example of a video signal and audio signals to be output, on which predistortion is not yet performed, according to the present invention.

Referring to FIG. 8, a video signal 8a and audio signals 8b_1 to 8b_6 start to be output at the same time and are ultimately output at the same time. Also, the audio signals 8b_1 to 8b_6 are the same as each other.

In FIG. 8, output sounds corresponding to the audio signal 1 8b_1 and the audio signal 2 8b_2 are assumed to be directly output via speakers without passing through sound transmission pipes. Also, output sounds corresponding to the audio signal 3 8b_3 and the audio signal 4 8b_4 are assumed to be transmitted through the first sound transmission pipes, which are identical to each other. Also, output sounds corresponding to the audio signal 5 8b_5 and the audio signal 6 8b_6 are assumed to be transmitted through the second sound transmission pipes, which are identical to each other. Here, the first sound transmission pipes are assumed to be shorter than the second sound transmission pipes.

When the sound system according to the conventional art, illustrated in FIG. 2, is used for the example illustrated in FIG. 8, because the speakers are located in the indoor space, the video signal 8a and the audio signals 8b_1 to 8b_6 may be output at the same time.

However, when the output sounds are transmitted using the sound transmission pipes as described in the embodiment of the present invention, the video signal and the audio signals may not be synchronized with each other, or the sound may be distorted.

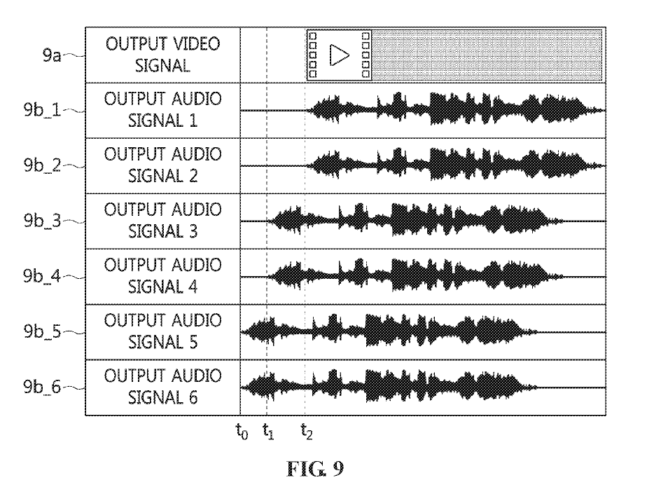

FIG. 9 is a view that shows an example of the result of adjustment of a delay in the example illustrated in FIG. 8 according to an embodiment of the present invention.

Referring to FIG. 9. because the example in FIG. 9 is the result of adjusting only the delay in the example illustrated in FIG. 8, there is no change in the waveforms of the audio signals 9b_1 to 9b_6 illustrated in FIG. 9, in comparison with the waveforms of the audio signals 8b_1 to 8b_6 illustrated in FIG. 8. That is, the waveforms of the audio signals 9b_1 to 9b_6 illustrated in FIG. 9 are identical to the waveforms of the audio signals 8b_1 to 8b_6 illustrated in FIG. 8.

Here, because output sounds corresponding to the audio signal 5 9b_5 and the audio signal 6 9b_6 are transmitted through the second sound transmission pipes, which are the longest, it takes the longest time t₂ for the output sounds to be transmitted.

Accordingly, the delay of the audio signal 5 9b_5 and the audio signal 6 9b_6 is not adjusted, and they start to be output at to identically to the example in FIG. 8.

Also, because output sounds corresponding to the audio signal 3 9b_3 and the audio signal 4 9b_4 are transmitted through the first sound transmission pipes, which are shorter than the second sound transmission pipes, the time (t₂-t₁), which is shorter than t₂, is taken for the output sounds to be transmitted. Here, t₂ is greater than t₁. That is, the output sounds corresponding to the audio signal 3 9b_3 and the audio signal 4 9b_4 are output earlier by t₁ than the output sounds corresponding to the audio signal 5 9b_5 and the audio signal 6 9b_6.

In order to solve this problem, the delay of the audio signal 3 9b_3 and the audio signal 4 9b_4 is adjusted by whereby the audio signal 3 9b_3 and the audio signal 4 9b_4 start to be output at t₁.

Also, because output sounds corresponding to the audio signal 1 9b_1 and the audio signal 2 9b_2 are directly output via speakers without passing through the sound transmission pipes, it takes no time for the output sounds to be transmitted. That is, the output sounds corresponding to the audio signal 1 9b_1 and the audio signal 2 9b_2 are output earlier by t₂ than the output sounds corresponding to the audio signal 5 9b_5 and the audio signal 6 9b_6.

In order to solve this problem, the delay of the audio signal 1 9b_1 and the audio signal 2 9b_2 is adjusted by t₂, whereby the audio signal 1 9b_1 and the audio signal 2 9b_2 start to be output at t₂.

Similarly, because it takes no time for the video signal 9b to be output, the video signal is output earlier by t₂ than the output sounds corresponding to the audio signal 5 9b_5 and the audio signal 6 9b_6.

Accordingly, the delay of the video signal 9b is also adjusted by t₂, whereby the video signal 9b starts to be output at t₂.

Accordingly, the problem in which a video signal and audio signals are not synchronized because output sounds are transmitted through sound transmission pipes may be solved.

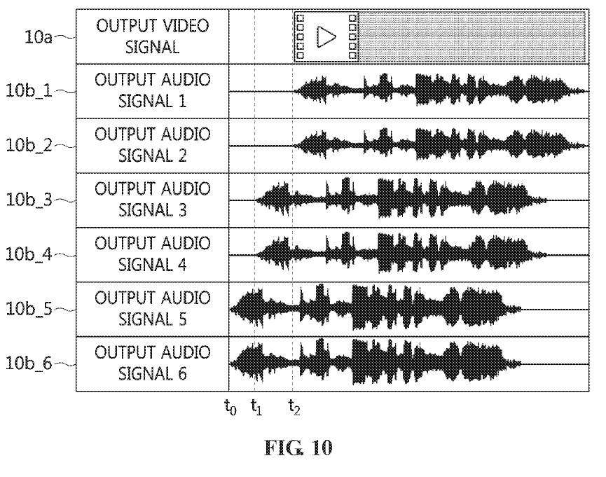

FIG. 10 is a view that shows an example of the result of adjustment of a level in the example illustrated in FIG. 9 according to an embodiment of the present invention.

Referring to FIG. 10, because the example in FIG. 10 is the result of adjusting only a level in the example illustrated in FIG. 9, the waveforms of the audio signals 10b_1 to 10b_6 illustrated in FIG. 10 differ from the waveforms of the audio signals 9b_1 to 9b_6 illustrated in FIG. 9 only in the amplitude thereof.

Here, because output sounds corresponding to the audio signal 5 10b_5 and the audio signal 6 10b_6 are transmitted through the second sound transmission pipes, which are identical to each other, the levels thereof are identically adjusted.

Here, the amount by which the level is adjusted may be set depending on the sound transmission pipe parameters corresponding to the second sound transmission pipes. Also, when an object, such as a screen or the like, is arranged in front of the second sound transmission pipes, the level may be adjusted in consideration thereof.

Also, because output sounds corresponding to the audio signal 3 10b_3 and the audio signal 4 10b_4 are transmitted through the first sound transmission pipes, which are identical to each other, the levels thereof are identically adjusted.

Here, the amount by which the level is adjusted may be set depending on the sound transmission pipe parameters corresponding to the first sound transmission pipes. Also, when an object, such as a screen or the like, is arranged in front of the first sound transmission pipes, the level may be adjusted in consideration thereof.

Also, because output sounds corresponding to the audio signal 1 10b_1 and the audio signal 2 10b_2 are directly output via the speakers without passing through sound transmission pipes, the levels thereof are not adjusted. Therefore, the audio signal 1 10b_1 and the audio signal 2 10b_2 illustrated in FIG. 10 are identical to the audio signal 1 9b_1 and the audio signal 2 9b_2 illustrated in FIG. 9, respectively.

Here, although the output sounds corresponding to the audio signal 1 10b_1 and the audio signal 2 10b_2 are directly output via the speakers, if an object, such as a screen or the like, is arranged in front of the corresponding speakers, the levels thereof may be adjusted in consideration thereof.

Accordingly, the problem in which the level of output sounds decreases when the output sounds are transmitted through sound transmission pipes may be solved.

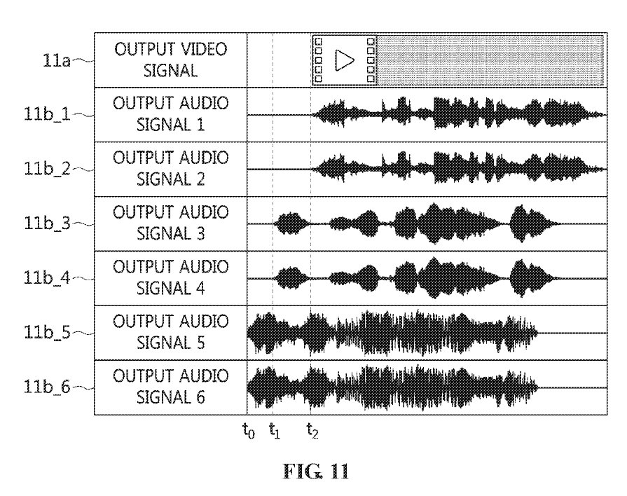

FIG. 11 is a view that shows an example of the result of adjusting equalization in the example illustrated in FIG. 10 according to an embodiment of the present invention.

Referring to FIG. 11, because the example in FIG. 11 is the result of adjusting equalization in the example illustrated in FIG. 10, the waveforms of the audio signals 11b_1 to 11b_6 illustrated in FIG. 11 may differ from the waveforms of the audio signals 10b_1 to 10b_6 illustrated in FIG. 10.

Here, because output sounds corresponding to the audio signal 5 11b_5 and the audio signal 6 11b_6 are transmitted through the second sound transmission pipes, which are identical to each other, equalization thereof is identically adjusted.

Here, the degree by which equalization is adjusted may be set depending on the sound transmission pipe parameters corresponding to the second sound transmission pipes.

Also, because output sounds corresponding to the audio signal 3 11b_3 and the audio signal 4 11b_4 are transmitted through the first sound transmission pipes, which are identical to each other, equalization thereof is identically adjusted.

Here, the degree by which equalization is adjusted may be set depending on the sound transmission pipe parameters corresponding to the first sound transmission pipes.

Also, because output sounds corresponding to the audio signal 1 11b_1 and the audio signal 2 11b_2 are directly output via speakers without passing through sound transmission pipes, equalization is not adjusted. Therefore, the audio signal 1 11b_1 and the audio signal 2 11b_2 illustrated in FIG. 11 are identical to the audio signal 1 10b_1 and the audio signal 2 10b_2 illustrated in FIG. 10, respectively.

Accordingly, the problem in which the output sounds are distorted because the output sounds are transmitted through the sound transmission pipes may be solved.

According to the present invention, because sound transmission pipes are used to output sounds, sounds may be output even in a space that is too small to install a speaker.

Also, according to the present invention, because predistortion is performed for audio signals to be output in consideration of the fact that output sounds are distorted while being transmitted through sound transmission pipes, the distortion may be compensated for, whereby sounds intended to be output may be listened to.

Also, according to the present invention, predistortion is complemented using output sounds transmitted through sound transmission pipes, whereby accuracy and reliability of predistortion may be improved.

Although specific embodiments have been described in the specification, they are not intended to limit the scope of the present invention. For the conciseness of the specification, descriptions of conventional electronic components, control systems, software, and other functional aspects thereof may be omitted. Also, lines connecting components or connecting members illustrated in the drawings show functional connections and/or physical or circuit connections, and may be represented as various functional connections, physical connections, or circuit connections that are capable of replacing or being added to an actual device. Also, unless specific terms, such as “essential”, “important”, or the like, are used, corresponding components may not be absolutely necessary.

Accordingly, the spirit of the present invention should not be construed as being limited to the above-described embodiments, and the entire scope of the appended claims and their equivalents should be understood as defining the scope and spirit of the present invention.

What is claimed is:

1. An apparatus for playing sounds indoors using sound transmission pipes, comprising:
a processor for extracting audio signals of one or more channels from source data and creating audio signals to be output;
speakers for outputting the audio signals; and
sound transmission pipes, connected with remote speakers that are parts of the speakers, for transmitting output sounds corresponding to the remote speakers.

2. The apparatus of claim 1, wherein:
the processor creates predistortion parameters using sound transmission pipe parameters and thereby performs predistortion for the audio signals to be output, and
the sound transmission pipe parameters include information about at least one of a material, a length, a size, and a shape of each of the sound transmission pipes.

3. The apparatus of claim 2, wherein:
the audio signals include side audio signals, among multi-channel audio signals, and
the sound transmission pipes are symmetrically installed on left and right sides of an indoor space.

4. The apparatus of claim 3, further comprising:
feedback microphones for creating feedback audio signals by receiving sounds transmitted through the sound transmission pipes,
wherein the processor performs supplementary distortion for the audio signals to be output, on which predistortion has been performed, using the feedback audio signals.

5. The apparatus of claim 3, wherein:
the predistortion includes distortion for a video signal to be output, and
the predistortion parameters include delay adjustment information for at least one of the video signal to be output and the audio signals to be output.

6. The apparatus of claim 3, wherein the predistortion parameters include equalization adjustment information for at least one of the audio signals to be output.

7. The apparatus of claim 3, wherein the predistortion parameters include level adjustment information for at least one of the audio signals to be output.

8. A method for playing sounds indoors using sound transmission pipes, comprising:
extracting audio signals of one or more channels from source data and creating audio signals to be output;
outputting the audio signals using speakers; and
transmitting output sounds corresponding to remote speakers, which are parts of the speakers, through sound transmission pipes connected with the remote speakers.

9. The method of claim 8, wherein creating the audio signals to be output comprises:
creating predistortion parameters using sound transmission pipe parameters; and
performing predistortion for the audio signals to be output using the predistortion parameters,
wherein the sound transmission pipe parameters include information about at least one of a material, a length, a size, and a shape of each of the sound transmission pipes.

10. The method of claim 9, wherein:
the audio signals include side audio signals, among multi-channel audio signals, and
the sound transmission pipes are symmetrically installed on left and right sides of an indoor space.

11. The method of claim 10, further comprising:
creating feedback audio signals by receiving sounds transmitted through the sound transmission pipes,
wherein creating the audio signals to be output further comprises performing supplementary distortion for the audio signals to be output, on which predistortion has been performed, using the feedback audio signals.

12. The method of claim 10, wherein:
the predistortion includes distortion for a video signal to be output, and
the predistortion parameters include delay adjustment information for at least one of the video signal to be output and the audio signals to be output.

13. The method of claim 10, wherein the predistortion parameters include equalization adjustment information for at least one of the audio signals to be output.

14. The method of claim 10, wherein the predistortion parameters include level adjustment information for at least one of the audio signals to be output.
